(19) United States
(12) Patent Application Publication
(10) Pub. No.: US 2021/0125887 A1
(43) Pub. Date: Apr. 29, 2021

(54) SEMICONDUCTOR APPARATUS

(71) Applicant: TOYOTA JIDOSHA KABUSHIKI KAISHA, Toyota-shi (JP)

(72) Inventor: Keigo INABA, Toyota-shi (JP)

(21) Appl. No.: 17/037,914

(22) Filed: Sep. 30, 2020

(30) Foreign Application Priority Data
Oct. 28, 2019 (JP) 2019-194859

(51) Int. Cl. H01L 23/31; H01L 23/495; H01L 23/00

(52) U.S. Cl. CPC H01L 23/3142; H01L 23/495; H01L 2224/30181; H01L 23/3121; H01L 24/30

(57) ABSTRACT

A semiconductor apparatus capable of sufficiently securing adhesion between a lead frame and sealing resin body. The semiconductor apparatus includes a lead frame, semiconductor device bonded to a mounting surface of the lead frame, and sealing resin body that covers the surface of the semiconductor device and a surrounding region of the semiconductor device on the mounting surface, in which in the surrounding region, a plurality of circular concave portions is formed with a predetermined pitch in a plurality of rows so as to surround the semiconductor device, and when the pitch and depth of concave portions arranged in at least the innermost peripheral row of the rows that surround the semiconductor device are represented as P[μm] and H[μm],respectively, and the flexural modulus of elasticity of the sealing resin body is represented as E[GPa], the following Formulae (1) and (2) are satisfied:

E[GPa]≤20[GPa] (1)

5≤86.4−5.45×E[GPa]+0.164×P[μm]≤H[μm] (2)

### CROSS REFERENCE TO RELATED APPLICATIONS

The present application claims priority from Japanese patent application JP 2019-194859 filed on Oct. 28, 2019, the entire content of which is hereby incorporated by reference into this application.

### BACKGROUND

### Technical Field

The present disclosure relates to a semiconductor apparatus including a lead frame, a semiconductor device bonded to the lead frame, and a sealing resin body that covers the lead frame and the semiconductor device.

### Description of Related Art

Semiconductor apparatuses including a lead frame, a semiconductor device bonded to the lead frame, and a sealing resin body that covers these have conventionally been known. As such a semiconductor apparatus, the one in which a surrounding portion of a semiconductor device in a lead frame or the like is provided with a streak-like recess has been known (see, for example, JP 2016-29676 A). In the semiconductor apparatus described in JP 2016-29676 A, the surrounding portion of the circuit pattern on which a semiconductor chip is mounted is provided with a streak-like recess having a depth greater than or equal to 1.75 μm to improve the adhesion of the mold resin (sealing resin body) to the circuit pattern.

### SUMMARY

However, in the semiconductor apparatus described in JP 2016-29676 A above, since the recess formed in the circuit pattern is shallow, the adhesion of the mold resin to the circuit pattern may be insufficient. In particular, in a semiconductor apparatus provided with a pair of lead frames so as to sandwich the semiconductor device in the thickness direction, a significant stress is generated in the lead frames, thereby possibly causing removal on the interface between the lead frames and the mold resin.

The present disclosure has been made in view of the foregoing, and provides a semiconductor apparatus capable of securing sufficient adhesion between the lead frame and the sealing resin body.

As a result of elaborated study, the inventors have found that in a semiconductor apparatus including a lead frame, a semiconductor device bonded to a mounting surface of the lead frame via a bonding layer, and a sealing resin body that covers the semiconductor device and the lead frame, on the mounting surface of the lead frame, the largest stress is generated in a region near the semiconductor device. Further, the inventors have found that in the structure in which a plurality of concave portions are formed in a plurality of rows on the mounting surface of the lead frame so as to surround the semiconductor device, the pitch and depth of the concave portions arranged in the innermost peripheral row and the flexural modulus of elasticity of the sealing resin body significantly affect the adhesion between the semiconductor device and the sealing resin body.

The present disclosure is based on the inventors' new findings, and the semiconductor apparatus according to the present disclosure includes a first lead frame, a semiconductor device bonded to a mounting surface of the first lead frame via a first bonding layer, and a sealing resin body that covers the surface of the semiconductor device and a surrounding region of the semiconductor device on the mounting surface, in which in the surrounding region, a plurality of circular concave portions is formed with a predetermined pitch in a plurality of rows so as to surround the semiconductor device, and when the pitch and the depth of the concave portions arranged in at least the innermost peripheral row of the plurality of rows disposed so as to surround the semiconductor device are represented as P[μm] and H[μm], respectively, and the flexural modulus of elasticity of the sealing resin body is represented as E[GPa], the following Formulae (1) and (2) are satisfied:

E[GPa]≤20[GPa] (1)

5≤86.4−5.45×E[GPa]+0.164×P[μm]≤H[μm] (2)

According to the semiconductor apparatus of the present disclosure, the pitch and depth of the concave portions arranged in the innermost peripheral row satisfy Formula (2). Thus, in the structure in which a plurality of concave portions is formed in a plurality of rows so as to surround the semiconductor device, the pitch and depth of the concave portions arranged in the innermost peripheral row are properly set, so that the adhesion of the sealing resin body to the first lead frame can be sufficiently secured. Therefore, even when a significant stress is generated in the first lead frame, the removal on the interface between the first lead frame and the sealing resin body can be sufficiently reduced.

In the aforementioned semiconductor apparatus, the concave portions arranged in each of the aforementioned rows may satisfy Formula (2) above. Thus, not only the concave portions arranged in the innermost peripheral row, but also those in all the rows disposed so as to surround the semiconductor device satisfy Formula (2), thereby enabling the adhesion of the sealing resin body to the first lead frame to be more sufficiently secured. This can sufficiently reduce the occurrence of the removal on the interface between the first lead frame and the sealing resin body.

In the aforementioned semiconductor apparatus, the plurality of concave portions may include first concave portions arranged in the innermost peripheral row, second concave portions arranged in the outermost peripheral row, and third concave portions arranged between the innermost peripheral row and the outermost peripheral row, the third concave portions being formed so as to have at least one of a larger pitch and a smaller depth than those of the first concave portions and the second concave portions. Thus, in forming the plurality of concave portions through laser processing, the processing time for forming the third concave portions can be reduced, as compared to a case in which the third concave portions are formed so as to have the same pitch and depth as those of the first concave portions and second concave portions. It should be noted that when the mounting surface of the lead frame is divided into three regions of a region near the semiconductor device, a region far from the semiconductor device, and an intermediate region therebetween, the stress generated in the intermediate region is smaller than those generated in the regions near and far from the semiconductor device. Therefore, even when the third concave portions are formed so as to have at least one of a larger pitch and a smaller depth than those of the first concave portions and second concave portions, the adhesion of the sealing resin body to the first lead frame can be sufficiently secured, and the removal on the interface between the first lead frame and the sealing resin body can also be sufficiently reduced.

The aforementioned semiconductor apparatus may further includes a metal block bonded, via a second bonding layer, to a surface of the semiconductor device, which is on a side opposite to the first lead frame, and a second lead frame bonded, via a third bonding layer, to a surface of the metal block, which is on a side opposite to the semiconductor device, in which the second lead frame has a facing surface disposed so as to face the metal block, a surrounding region of the metal block on the facing surface is covered with the sealing resin body, in the facing surface, a plurality of circular concave portions is formed with a predetermined pitch in a plurality of rows so as to surround the metal block, and the concave portions arranged in at least the innermost peripheral row of the plurality of rows disposed so as to surround the metal block satisfy the aforementioned Formula (2). Thus, in the structure in which the plurality of concave portions is formed in a plurality of rows so as to surround the third bonding layer, the pitch and depth of the concave portions arranged in the innermost peripheral row are properly set, so that the adhesion of the sealing resin body to the second lead frame can be sufficiently secured. Therefore, even when a significant stress is generated in the second lead frame, the removal on the interface between the second lead frame and the sealing resin body can be sufficiently reduced.

It should be noted that in the structure in which the metal block and the second lead frame are stacked on the surface of the semiconductor device, which is on a side opposite to the first lead frame (the structure in which the semiconductor device is sandwiched between the first lead frame and the second lead frame), the constraining force of the sealing resin body is large, which relatively increases the stress generated in the first lead frame and the second lead frame. Thus, it is particularly effective to sufficiently secure the adhesion between the first lead frame and second lead frame and the sealing resin body by forming a plurality of concave portions of the first lead frame and second lead frame so as to have the proper pitch and depth.

### EFFECT

According to a semiconductor apparatus of the present disclosure, sufficient adhesion between a lead frame and a sealing resin body can be secured.

### BRIEF DESCRIPTION OF THE DRAWINGS

FIG. 1 is a schematic cross-sectional view of a semiconductor apparatus according to a first embodiment of the present disclosure;

FIG. 2 is a plan view illustrating the structure of a mounting surface of a lead frame of the semiconductor apparatus according to the first embodiment of the present disclosure;

FIG. 3 is a view illustrating the structure of a concave portion of the lead frame of the semiconductor apparatus according to the first embodiment of the present disclosure;

FIG. 4 is a view for explaining experiments conducted for deriving Formula (2);

FIG. 5 is a chart showing relations between actually measured values and calculated values of adhesion strength;

FIG. 6 is a plan view illustrating the structure of a mounting surface of a lead frame of the semiconductor apparatus according to a second embodiment of the present disclosure;

FIG. 7 is a chart showing thermal stress analysis results of the stress generated at given positions of a surrounding region in the lead frame; and

FIG. 8 is a schematic cross-sectional view of a modification of the semiconductor apparatus according to the present disclosure.

### DETAILED DESCRIPTION OF THE EMBODIMENTS

A semiconductor apparatus according to an embodiment of the present disclosure will be described below.

### First Embodiment

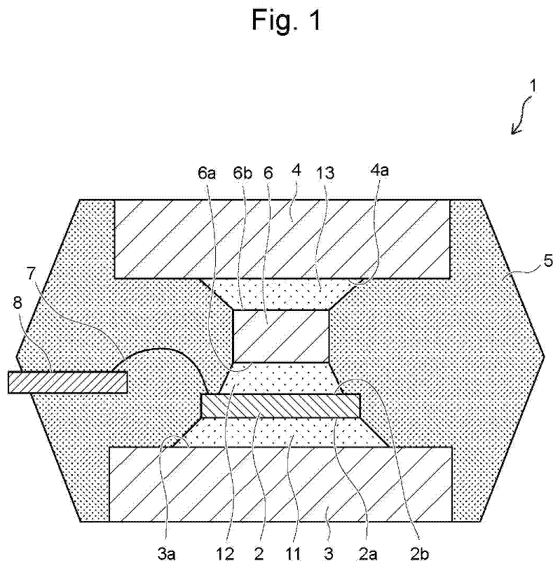

First, with reference to FIG. 1, the structure of a semiconductor apparatus 1 according to a first embodiment of the present disclosure will be described. FIG. 1 is a schematic cross-sectional view of the semiconductor apparatus 1 according to the first embodiment of the present disclosure.

The semiconductor apparatus 1 according to the present embodiment includes at least a semiconductor device 2, a lead frame (first lead frame) 3 and a lead frame (second lead frame) 4 that are disposed so as to sandwich the semiconductor device 2 in the thickness direction, and a sealing resin body 5 that covers both the lead frames 3 and 4 and the semiconductor device 2. The lead frames 3 and 4 are respectively disposed on a collector side and an emitter side of the semiconductor device 2.

In the semiconductor apparatus 1 of the present embodiment, one surface (lower surface in FIG. 1) 2a of the semiconductor device 2 is bonded to a mounting surface 3a of the lead frame 3 via a solder layer (first bonding layer) 11. Meanwhile, the other surface (surface on the opposite side, upper surface in FIG. 1) 2b of the semiconductor device 2 is bonded to a metal block 6 via a solder layer 12. A surface 6b of the metal block 6, which is opposite to a surface 6a to which the solder layer 12 is bonded, is bonded, via a solder layer 13, to a facing surface 4a facing the metal block 6 of the lead frame 4. Further, the semiconductor apparatus 1 includes a wire 7 made of Al, Cu, or Au and a terminal 8 made of Cu. The wire 7 electrically connects the semiconductor device 2 and the terminal 8.

Examples of the semiconductor device 2 include, but not limited to, a power device having, for example, a Si substrate or a SiC substrate.

The lead frame 3 includes aluminum, copper, or an alloy thereof, and a plated layer may be formed on a side surface of the lead frame 3 and the mounting surface 3a on which the semiconductor device 2 is mounted. In the present embodiment, the lead frame 3 is made of copper and is not plated. Similarly, the lead frame 4 includes aluminum, copper, or an alloy thereof, and a plated layer may be formed on a side surface of the lead frame 4 and the facing surface 4a on which the metal block 6 is disposed. In the present embodiment, the lead frame 4 is made of copper and is not plated.

The sealing resin body 5 covers the semiconductor device 2, the lead frames 3 and 4, the solder layers 11 to 13, the metal block 6, the wire 7, and the terminal 8. However, a surface on the side opposite to the mounting surface 3a of the lead frame 3, a surface on the side opposite to the facing surface 4a of the lead frame 4, and an end of the terminal 8 are exposed from the sealing resin body 5. The sealing resin body 5 is made of a thermosetting resin, such as an epoxy resin or imide-based resin. Further, in order to apply, to the sealing resin body 5, desired physical properties such as improved thermal conductivity and thermal expansion, the thermosetting resin may contain an inorganic filler, such as silica, alumina, boron nitride, silicon nitride, silicon carbide, or a magnesium oxide. The particle size of the filler contained in the sealing resin body 5 is, for example, between 20 μm and 70 μm, inclusive, but is not particularly limited thereto.

The solder layers 11 to 13 may be either a Pb-based solder or a Pb-free solder, but in some embodiments, they may be a Pb-free solder. Examples of such a Pb-free solder include Sn—Ag-based solder, Sn—Cu-based solder, Sn—Cu—Ni-based solder, Sn—Ag—Cu-based solder, Sn—Zn-based solder, or Sn—Sb-based solder.

The metal block 6 is adapted to adjust the height of the semiconductor apparatus 1, and includes, for example, aluminum, copper, or an alloy thereof.

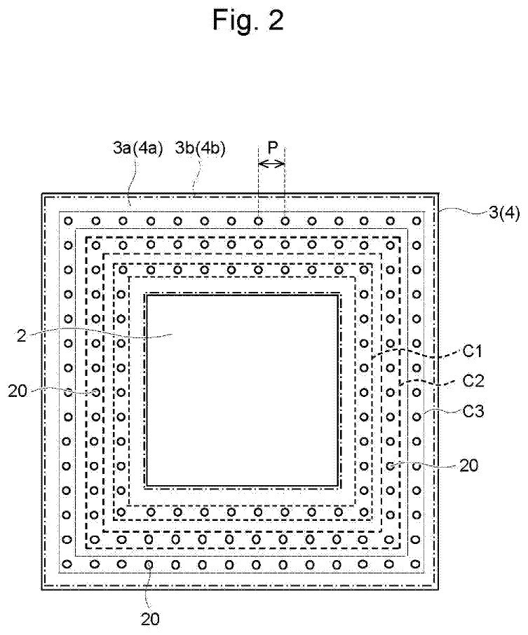

Herein, in the present embodiment, as illustrated in FIG. 2, the mounting surface 3a of the lead frame 3 has a surrounding region 3b that surrounds the semiconductor device 2. In at least the surrounding region 3b of the mounting surface 3a, a plurality of dotted circular concave portions 20 is formed with a predetermined pitch P in a plurality of rows (herein, three rows) C1, C2, and C3, so as to surround the semiconductor device 2. The concave portions 20 are provided to improve the adhesion between the sealing resin body 5 and the lead frame 3. It should be noted that FIG. 2 illustrates an example in which the plurality of concave portions 20 are arranged in a matrix, but the plurality of concave portions 20 may be arranged in a staggered manner.

The method of forming the concave portions 20 may include, but not particularly limited to, laser processing, an etching technique, or the like. However, in some embodiments, the concave portions 20 may be formed using laser processing. The type of laser is not particularly limited, and for example, fiber laser, solid laser, liquid laser, gas laser, or semiconductor laser may be used to form the concave portions 20. When the etching technique is used to form the concave portions 20, for example, an iron chloride solution may be used to form the concave portions 20.

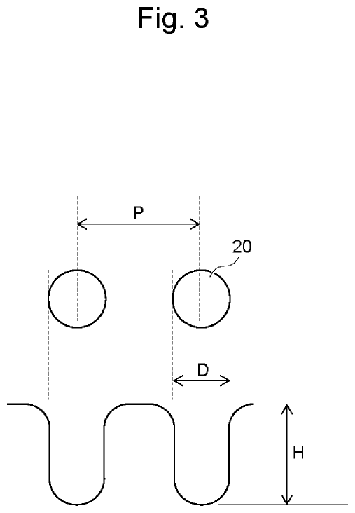

The concave portions 20 are each formed in a circular shape as seen in plan view, as illustrated in FIG. 3, and an opening diameter D of each concave portion 20 is in the range of greater than or equal to 30 μm and less than a pitch P. Further, when the sealing resin body 5 contains the aforementioned filler, the opening diameter D of the concave portion 20 may be in the range of greater than or equal to 70 μm and less than the pitch P. The reason why the lower limit of the opening diameter D of the concave portion 20 is set to 70 μm is that since the upper limit of the particle size of the filler (not shown) contained in the sealing resin body 5 is 70 μm, when the opening diameter D is set to be less than 70 μm, the filler is caught in the opening end of the concave portion 20, which may fail to fill the concave portion 20 with the sealing resin body 5. If there are concave portions 20 that are not filled with the sealing resin body 5, the adhesion between the sealing resin body 5 and the lead frame 3 may decrease. Meanwhile, the reason why the upper limit of the opening diameter D of the concave portion 20 is set to be less than the pitch P is to prevent adjacent concave portions 20 from coupling with each other.

Further, the opening diameter D of the concave portion 20 may be between 70 μm and 110 μm, inclusive, and further, may be between 80 μm and 90 μm, inclusive. When the opening diameter D of the concave portion 20 is set to be smaller than or equal to 110 μm, the concave portion 20 may easily be formed using a laser device on the market. Furthermore, when the opening diameter D of the concave portion 20 is set to be greater than or equal to 80 μm, the filler to be caught in the opening end of the concave portion 20 can sufficiently be suppressed. When the opening diameter D of the concave portion 20 is set to be smaller than or equal to 90 μm, the energy amount required for forming the concave portions 20 can be suppressed, that is, the processing time can be reduced.

A depth H of the concave portion 20 is in the range of greater than or equal to 5 μm and less than the plate thickness (for example, 2000 μm) of the lead frame 3. The reason why the lower limit of the depth H of the concave portion 20 is set to 5 μm is that when the depth H of the concave portion 20 is set to be less than 5 μm, the adhesion between the sealing resin body 5 and the concave portion 20 cannot be secured. The reason why the upper limit of the depth H of the concave portion 20 is set to be less than the plate thickness of the lead frame 3 is to prevent the lead frame 3 from being pierced in the thickness direction by the concave portions 20 formed.

Further, in the present embodiment, when the pitch and depth of the concave portions 20 arranged in at least the innermost peripheral row C1 of the plurality of rows C1 to C3 (see FIG. 2) disposed so as to surround the semiconductor device 2 are represented by P[μm] and H[μm], respectively, and the flexural modulus of elasticity of the sealing resin body 5 is represented by E[GPa], the following Formulae (1) and (2) are satisfied. Thus, as will be described later, the pitch P[μm] and depth H[μm] of the concave portions 20 arranged in at least the innermost peripheral row C1 are properly set, thereby enabling to secure sufficient adhesion of the sealing resin body 5 to the lead frame 3.

E[GPa]≤20[GPa] (1)

5≤86.4−5.45×E[GPa]+0.164×P[μm]≤H[μm] (2)

In some embodiments, the concave portions 20 arranged in the row C1 all may be formed so as to have the same pitch P and the same depth H. However, all the concave portions 20 are not necessarily formed so as to have the same pitch P and the same depth H. In that case, each concave portion 20 only needs to satisfy the aforementioned Formula (2).

It should be noted that in the present embodiment, the concave portions 20 arranged in the rows C2 and C3 of the plurality of rows C1 to C3 disposed so as to surround the semiconductor device 2 also satisfy the aforementioned Formula (2). In addition, all the concave portions 20 arranged in the rows C2 and C3 are formed so as to have the same pitch P and the same depth H as those of the concave portions 20 arranged in the row C1.

Further, in the present embodiment, in at least a surrounding region 4b surrounding the metal block 6 of the facing surface 4a of the lead frame 4, similarly to the lead frame 3, a plurality of dotted circular concave portions 20 is formed with a predetermined pitch in a plurality of rows (herein, three rows) C1, C2, and C3 so as to surround the metal block 6 and the solder layer 13. It should be noted that since the concave portions 20 of the lead frame 4 have the same structure and the same purpose as those of the concave portions 20 of the lead frame 3, the explanation is made using the same reference numerals. Further, for simplifying the preparation of drawings, the explanation of the concave portions 20 of the lead frame 4 will also be made with reference to FIG. 2 and FIG. 3 similarly to those of the lead frame 3.

The opening diameter D of the concave portion 20 of the lead frame 4 is in the range of greater than or equal to 70 μm and less than a pitch. The depth H of the concave portion 20 of the lead frame 4 is in the range of greater than or equal to 5 μm and less than the plate thickness (for example, 2000 μm) of the lead frame 4. Further, in the present embodiment, the concave portions 20 arranged in at least the innermost peripheral row C1 of the plurality of rows C1 to C3 disposed so as to surround the semiconductor device 2 satisfy the aforementioned Formula (2). Thus, as will be described later, the pitch P[μm] and depth H[μm] of the concave portions 20 arranged in at least the innermost peripheral row C1 are properly set, thereby enabling to secure sufficient adhesion of the sealing resin body 5 to the lead frame 4. It should be noted that the other part of the structure and the method for forming of the concave portions 20 of the lead frame 4 are the same as those of the concave portions 20 of the lead frame 3.

Next, how the aforementioned Formula (2) is derived will be described.

Various factors are assumed to affect the adhesion strength between the lead frames 3 and 4 and the sealing resin body 5. The factors include, for example, the pitch and depth of the concave portions 20 and the flexural modulus of elasticity of the sealing resin body 5. Thus, a multiple regression analysis was conducted by setting the adhesion strength as a response variable, and the pitch and depth of the concave portions 20 and the flexural modulus of elasticity of the sealing resin body 5 as explanatory variables. For such a multiple regression analysis, the following experiments were conducted.

### EXPERIMENTS

### Sample 1

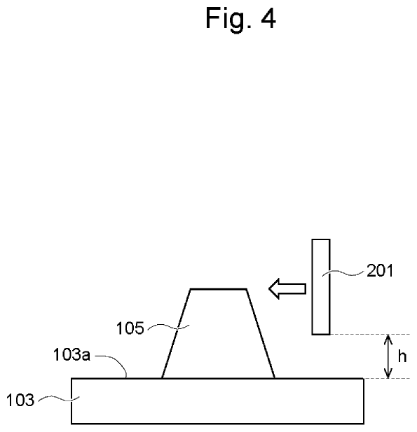

On a surface 103a of a copper plate 103 (see FIG. 4) made of oxygen-free copper (C1020), a plurality of concave portions 20 were formed in a matrix. At this time, using fiber laser to which Yb was added as a laser active substance, the concave portions 20 were formed with an output of 25W and a pulse period of 40 μsec. Further, the pitch and depth of the concave portions 20 were set to 108.6 μm and 5.4 μm, respectively. Then, as illustrated in FIG. 4, on the surface 103a of the copper plate 103, a resin body 105 made of an epoxy resin containing an inorganic filler having a particle size of smaller than or equal to 70 μm was formed. At this time, the resin body 105 was formed in a truncated cone shape having a bottom area of 10 mm², a height of 4 mm, and a taper angle of 7°, and the flexural modulus of elasticity of the resin body 105 was set to 18.0 GPa.

### Sample 2

The pitch and the depth of the concave portions 20 were set to 109.5 μm and 20.3 μm, respectively. The flexural modulus of elasticity of the resin body 105 was set to 10.8 GPa. The other part of the structure was the same as that of Sample 1.

### Sample 3

The pitch and the depth of the concave portions 20 were set to 111.1 μm and 101.2 μm, respectively. The flexural modulus of elasticity of the resin body 105 was set to 20.0 GPa. The other part of the structure was the same as that of Sample 1.

### Sample 4

The pitch and the depth of the concave portions 20 were set to 111.1 μm and 101.2 μm, respectively. The flexural modulus of elasticity of the resin body 105 was set to 18.0 GPa. The other part of the structure was the same as that of Sample 1.

### Sample 5

The pitch and the depth of the concave portions 20 were set to 111.1 μm and 101.2 μm, respectively. The flexural modulus of elasticity of the resin body 105 was set to 10.8 GPa. The other part of the structure was the same as that of Sample 1.

### Sample 6

The pitch and the depth of the concave portions 20 were set to 168.1 μm and 5.4 μm, respectively. The flexural modulus of elasticity of the resin body 105 was set to 20.0 GPa. The other part of the structure was the same as that of Sample 1.

### Sample 7

The pitch and the depth of the concave portions 20 were set to 168.1 μm and 20.4 μm, respectively. The flexural modulus of elasticity of the resin body 105 was set to 18.0 GPa. The other part of the structure was the same as that of Sample 1.

### Sample 8

The pitch and the depth of the concave portions 20 were set to 168.6 μm and 99.1 μm, respectively. The flexural modulus of elasticity of the resin body 105 was set to 10.8 GPa. The other part of the structure was the same as that of Sample 1.

### Sample 9

The pitch and the depth of the concave portions 20 were set to 409.5 μm and 5.8 μm, respectively. The flexural modulus of elasticity of the resin body 105 was set to 10.8 GPa. The other part of the structure was the same as that of Sample 1.

### Sample 10

The pitch and the depth of the concave portions 20 were set to 409.5 μm and 20.5 μm, respectively. The flexural modulus of elasticity of the resin body 105 was set to 20.0 GPa. The other part of the structure was the same as that of Sample 1.

### Sample 11

The pitch and the depth of the concave portions 20 were set to 410.2 μm and 99.2 μm, respectively. The flexural modulus of elasticity of the resin body 105 was set to 18.0 GPa. The other part of the structure was the same as that of Sample 1.

It should be noted that in each sample, the depth of each concave portion 20 was adjusted by adjusting the laser irradiation time, and the opening diameter D of each concave portions 20 of Samples 1 to 11 was between 70 μm and 110 μm, inclusive.

Further, the adhesion strength of Samples 1 to 11 was measured. Specifically, with a height h of a tool 201 relative to the surface 103a of the copper plate 103 set to 100 μm, by pressing the tool 201 against the resin body 105 at a moving velocity of 50 μm/s, the strength with which the resin body 105 is removed from the copper plate 103 was measured. The obtained strength was divided by the bottom area of the resin body 105, so that the adhesion strength [MPa] was calculated. Then, using the results, a multiple regression analysis was conducted by setting the adhesion strength as a response variable, and the pitch P[μm] and depth H[μm] of the concave portions 20 and the flexural modulus of elasticity E[GPa] of the sealing resin body 5 as explanatory variables. As a result, the following Formula (3) was obtained.

adhesion strength [MPa]=0.22×H[μm]+1.2×E[GPa]−0.036×P[μm]−2.5 (3)

From the aforementioned Formula (3), it has been proved that as the depth H of the concave portion 20 increases, the adhesion strength increases, as the flexural modulus of elasticity E increases, the adhesion strength increases, and as the pitch P of the concave portions 20 increases, the adhesion strength decreases. Then, the adhesion strength of Samples 1 to 11 was calculated using the aforementioned Formula (3). The results are shown in Table 1.

TABLE 1

| | | | Flexural modulus of | Calculated value of |
|---|---|---|---|---|
| | Pitch | Depth | elasticity | adhesion strength |
| Sample | [μm] | [μm] | [GPa] | [MPa] |
| 1 | 108.6 | 5.4 | 18.0 | 16.4 |
| 2 | 109.5 | 20.3 | 10.8 | 11 |
| 3 | 111.1 | 101.2 | 20.0 | 39.8 |
| 4 | 111.1 | 101.2 | 18.0 | 37.4 |
| 5 | 111.1 | 101.2 | 10.8 | 28.7 |
| 6 | 168.1 | 5.4 | 20.0 | 16.6 |
| 7 | 168.1 | 20.4 | 18.0 | 17.5 |
| 8 | 168.6 | 99.1 | 10.8 | 26.2 |
| 9 | 409.5 | 5.8 | 10.8 | −3 |
| 10 | 409.5 | 20.5 | 20.0 | 11.3 |
| 11 | 410.2 | 99.2 | 18.0 | 26.2 |

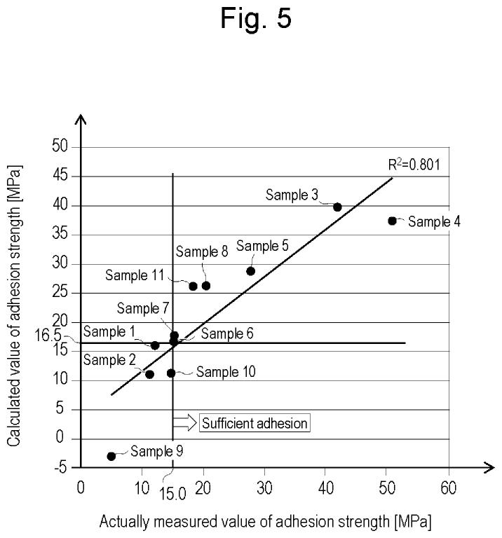

Further, the relations between the adhesion strength actually measured in the aforementioned experiments and the adhesion strength calculated by using the aforementioned Formula (3) regarding Samples 1 to 11 are shown in FIG. 5. The R² (coefficient of determination) calculated for the data shown in FIG. 5 was about 0.801, which proves that the prediction accuracy of the aforementioned Formula (3) is sufficiently high.

Herein, the inventors have found that in the semiconductor apparatus 1 having the structure in which the lead frames 3 and 4 are provided on the both sides of the semiconductor device 2 in the thickness direction as illustrated in FIG. 1, when the actually measured value of the adhesion strength at 25° C. is greater than or equal to 15.0 MPa, the adhesion required for the semiconductor apparatus 1 can be sufficiently secured. As illustrated in FIG. 5, the actually measured values of the adhesion strength of Samples 3 to 8 and 11 are greater than or equal to 15.0 MPa. Meanwhile, the actually measured values of the adhesion strength of Samples 1, 2, 9, and 10 are less than 15.0 MPa. Therefore, FIG. 5 can confirm that when the calculated values of the adhesion strength are between those of Sample 1 to Sample 6, that is, greater than or equal to 16.5 MPa, the adhesion required for the semiconductor apparatus 1 can be sufficiently secured.

Herein, by setting the adhesion strength obtained by using the aforementioned Formula (3) to be greater than or equal to 16.5 MPa and converting the formula into a formula using the depth H [μm], the following Formula (4) is obtained.

86.4−5.45×E[GPa]+0.164×P[μm]≤H[μm] (4)

Since the depth H[μm] of the concave portion 20 is greater than or equal to 5 μm as described above, the aforementioned Formula (2) is obtained from the aforementioned Formula (4). Thus, by setting the pitch P and the depth H of the concave portions 20 arranged in the plurality of rows C1 to C3 of the lead frames 3 and 4 so as to satisfy the aforementioned Formula (2), the adhesion of the sealing resin body 5 to the lead frames 3 and 4 can be sufficiently secured. Therefore, even when a significant stress is generated in the lead frames 3 and 4, the removal on the interface between the lead frames 3 and 4 and the sealing resin body 5 can be sufficiently reduced. It should be noted that the pitch P and the depth H of the concave portions 20 arranged in at least the innermost peripheral row C1 of the lead frames 3 and 4 only need to satisfy the aforementioned Formula (2), as will be described later. In this case also, the adhesion of the sealing resin body 5 to the lead frames 3 and 4 can be sufficiently secured.

It should be noted that, for example, the opening diameter D of the concave portion 20 is assumed to be a factor that may affect the adhesion strength between the lead frames 3 and 4 and the sealing resin body 5. The results of the multiple regression analysis conducted by adding the opening diameter D of the concave portion 20 and other parameters to the explanatory variables proved that the contribution (the degree of the effect) of the opening diameter D and other parameters to the adhesion strength was very small enough to be ignored, which is not explained in the aforementioned experiments. The reason why the contribution of the opening diameter D to the adhesion strength is very small is considered to be the following. For securing the adhesion strength between the copper plate 103 and the resin body 105, whether the resin body 105 enters the concave portion 20 is important. When the opening diameter D of the concave portion 20 is set to be in the range of those of the concave portions 20 of Samples 1 to 11 of the aforementioned experiments (between 70 μm and 110 μm, inclusive), since the opening diameter D is large relative to the particle size of the filler, the resin body 105 sufficiently enters the concave portion 20. Thus, the effect of the opening diameter D of the concave portion 20 on the adhesion strength is considered very small.

Further, since the effect of the opening diameter D of the concave portion 20 on the adhesion strength is very small, even when the opening diameter D of the concave portion 20 is increased, the adhesion strength is not improved. Therefore, for example, when the adjacent concave portions 20 are continuously formed, they form one large concave portion, and thus, the adhesion strength is hardly improved. That is, even when one rectangular recess surrounding the semiconductor device 2 is formed by connecting the adjacent concave portions 20 in each of the plurality of rows C1 to C3 illustrated in FIG. 2, it is difficult to sufficiently secure the adhesion strength.

Therefore, as disclosed in, for example, the aforementioned JP 2016-29676 A, even when a streak-like recess is formed in a circuit pattern, it is difficult to sufficiently secure the adhesion of the mold resin to the circuit pattern. In addition, as disclosed in, for example, JP 2009-177072 A, even when the entire surface of a wiring layer is provided with a minute concave-convex shape with a size of 10 nm to 300 nm, it is difficult to sufficiently secure the adhesion strength of the sealing resin layer to the wiring layer.

### Second Embodiment

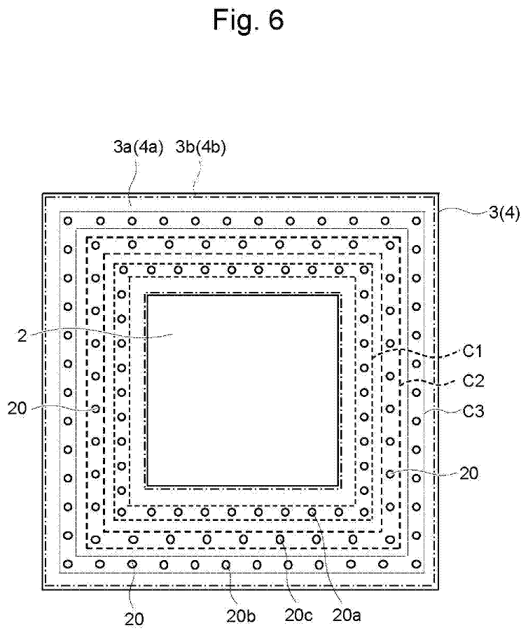

Next, the structure of the semiconductor apparatus 1 according to a second embodiment of the present disclosure will be described. In the second embodiment, as illustrated in FIG. 6, a case in which the concave portions 20 arranged in the row C2 are formed so as to have at least one of a larger pitch and a smaller depth than those of the concave portions 20 arranged in the rows C1 and C3, different from the aforementioned first embodiment, will be described.

In the semiconductor apparatus 1 of the second embodiment, similarly to the aforementioned first embodiment, the depth H of all the concave portions 20 of the lead frame 3 is set to be in the range of greater than or equal to 5 μm and less than the plate thickness (for example, 2000 μm) of the lead frame 3.

The plurality of concave portions 20 include a plurality of concave portions (first concave portions) 20a arranged in an innermost peripheral row C1, a plurality of concave portions (second concave portions) 20b arranged in an outermost peripheral row C3, and a plurality of concave portions (third concave portions) 20c arranged between the innermost peripheral row C1 and the outermost peripheral row C3.

In the present embodiment, only the concave portions 20a satisfy the aforementioned Formula (2), while the concave portions 20b and 20c do not satisfy the aforementioned Formula (2). The concave portions 20b are formed so as to have at least one of a larger pitch and a smaller depth than those of the concave portions 20a. Further, the concave portions 20c are formed so as to have at least one of a larger pitch and a smaller depth than those of the concave portions 20a and 20b. It should be noted that FIG. 6 shows a case in which the concave portions 20b are formed so as to have a larger pitch than that of the concave portions 20a, and the concave portions 20c are formed so as to have a larger pitch than those of the concave portions 20a and 20b.

Further, similarly to the aforementioned first embodiment, the concave portions 20 of the lead frame 4 all have the depth H in the range of greater than or equal to 5 μm and less than the plate thickness (for example, 2000 μm) of the lead frame 4.

Furthermore, similarly to the concave portions 20 of the lead frame 3, the concave portions 20 of the lead frame 4 include the plurality of concave portions 20a arranged in the innermost peripheral row C1, the plurality of concave portions 20b arranged in the outermost peripheral row C3, and the plurality of concave portions 20c arranged between the innermost peripheral row C1 and the outermost peripheral row C3.

Moreover, similarly to the lead frame 3, in the lead frame 4, only the concave portions 20a satisfy the aforementioned Formula (2), while the concave portions 20b and 20c do not satisfy the aforementioned Formula (2). The concave portions 20b are formed so as to have at least one of a larger pitch and a smaller depth than those of the concave portions 20a. Further, the concave portions 20c are formed so as to have at least one of a larger pitch and a smaller depth than those of the concave portions 20a and 20b.

In the present embodiment, as described above, the concave portions 20c are formed so as to have at least one of a larger pitch P and a smaller depth H than those of the concave portions 20a and 20b. This can reduce the processing time for forming the concave portions 20c in forming the plurality of concave portions 20 through laser processing, as compared to a case in which the concave portions 20c are formed so as to have the same pitch P and the same depth H as those of the concave portions 20a and 20b. It should be noted that, for example, when the mounting surface 3a of the lead frame 3 is divided into three regions of a region near the semiconductor device 2, a region far from the semiconductor device 2, and an intermediate region therebetween, the stress generated in the intermediate region is smaller than those generated in the regions near and far from the semiconductor device 2, as will be described later. The same is also true of the facing surface 4a of the lead frame 4. Thus, even when the concave portions 20c are formed so as to have at least one of a larger pitch P and a smaller depth H than those of the concave portions 20a and 20b, the adhesion of the sealing resin body 5 to the lead frames 3 and 4 can be sufficiently secured, and also, the removal on the interface between the lead frames 3 and 4 and the sealing resin body 5 can be sufficiently reduced.

Next, the method of setting the pitch or the depth of the concave portions 20a to 20c will be described. Herein, a case in which the concave portions 20a to 20c have the same pitch and different depths will be described.

The stress generated in the mounting surface 3a of the lead frame 3 was obtained through the thermal stress analysis using a model with the structure illustrated in FIG. 1. Specifically, SiC was used as the material for the semiconductor device 2, oxygen-free copper was used as the material for the lead frames 3 and 4, the metal block 6, and the terminal 8, Sn—Cu—Ni-based solder was used as the material for the solder layers 11 to 13, and Al was used as the material for the wire 7. Further, the flexural modulus of elasticity of the sealing resin body 5 was set to 16.0[GPa].

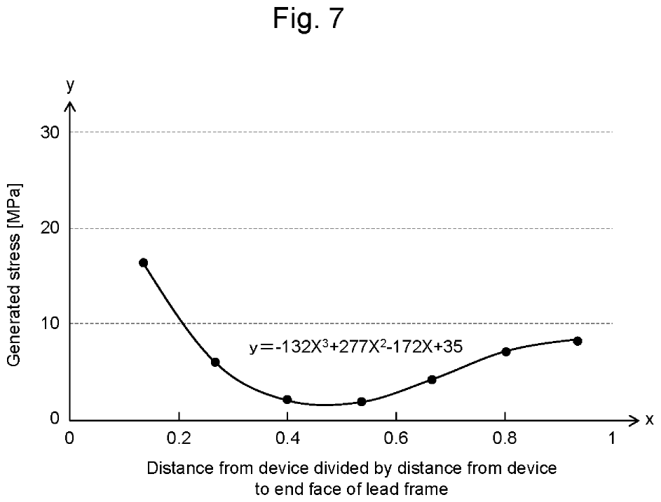

Then, the stress generated at given positions in the surrounding region 3b of the lead frame 3 at 25° C. was obtained. At this time, when the ratio obtained by dividing the distance from the end face of the semiconductor device 2 to a given position by the distance from the end face of the semiconductor device 2 to the end face of the lead frame 3 was represented as x, and the stress generated at the given position was represented as y, the following Formula (5) regarding x and y was obtained. The results are shown in FIG. 7 and Table 2.

y=−132·x³+277·x²−172·x+35 (5)

TABLE 2

| Distance from device/ | | | |
|---|---|---|---|
| distance from device to | Generated | Required | Adhesion strength |
| end face of lead frame | stress | depth | obtained |
| (=ratio x) | [MPa] | [μm] | [MPa] |
| 0.13 | 16.5 | 65 | 16.6 |
| 0.27 | 5.9 | 20 | 6.7 |
| 0.40 | 2.3 | 5 | 3.4 |
| 0.53 | 1.7 | 5 | 3.4 |
| 0.67 | 4.0 | 10 | 4.5 |
| 0.80 | 7.2 | 25 | 7.8 |
| 0.93 | 8.2 | 30 | 8.9 |

As shown in FIG. 7 and Table 2, in the surrounding region 3b on the mounting surface 3a of the lead frame 3, the stress generated in the region nearest to the semiconductor device 2 (herein, the region where the concave portions 20a were arranged) was the largest, and the stress generated in the region farthest from the semiconductor device 2 (herein, the region where the concave portions 20b were arranged) was the second largest. And, the stress generated in the intermediate region between the end face of the semiconductor device 2 and the end face of the lead frame 3 (herein, the region where the concave portions 20c were arranged) was the smallest.

As described above, the stress generated in the mounting surface 3a of the lead frame 3 is not uniform. Thus, in the region where a large stress is generated, the concave portions 20 need to be formed so as to satisfy the aforementioned Formula (2), while in the region where the generated stress is small, the concave portions 20 do not need to be formed so as to satisfy the aforementioned Formula (2).

It should be noted that the reason why the stress generated in the region nearest to the semiconductor device 2 is the largest is that since the semiconductor device 2 is a heat generating body, regions nearer to the semiconductor device 2 have higher temperatures. Meanwhile, in the region nearest to the semiconductor device 2, since the constraining force to suppress the deformation due to thermal expansion is large, the generated stress is considered to become the largest.

Next, as shown in Table 2, the depth H[μm] required for the concave portion 20 and the adhesion strength [MPa] to be obtained at seven positions (positions where the ratio x is 0.13, 0.27, 0.40, 0.53, 0.67, 0.80, and 0.93) are determined. Herein, the pitch P[μm] of the concave portions 20 is set to, for example, 400 μm.

For example, at the position where the ratio x is 0.13, the generated stress is 16.5[MPa], and thus, the following Formula (6) needs to be satisfied from the aforementioned Formula (3).

16.5[MPa]≤adhesion strength to be obtained [MPa]=0.22×H[μm]+1.2×16.0[GPa]−0.036×400[μm]−2.5 (6)

The adhesion strength obtained using the aforementioned Formula (6) when the depth H is greater than or equal to 65 μm is greater than or equal to 16.6[MPa], and thus, sufficient adhesion can be secured. The required depth H[μm] and the adhesion strength [MPa] to be obtained at the positions where the ratio x is 0.27, 0.40, 0.53, 0.67, 0.80, and 0.93 can also be similarly determined.

Accordingly, for example, when the pitch of the concave portions 20 is set to 400 μm, by setting the depths of the concave portions 20a, 20b, and 20c to 65 μm, 30 μm, and 5 μm, respectively, the sufficient adhesion can be secured. It is needless to say that when the depths of the concave portions 20a, 20b, and 20c are set to greater than 65 μm, 30 μm, and 5 μm, respectively, the adhesion is further improved.

It should be noted that also for the concave portions 20a to 20c having the same depth and different pitches, the aforementioned Formula (3) can be used to easily determine the pitches required for the concave portions 20a to 20c.

The entire part of the embodiment disclosed herein is exemplary, and should not be considered restrictive. The scope of the present disclosure is not specified by the description of the aforementioned embodiments, but the scope of the claims. Further, the present disclosure encompasses any modifications that are equivalent in meaning to and are within the scope of the claims.

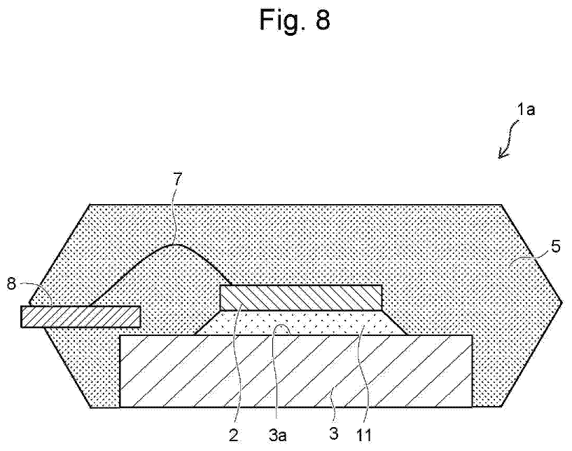

For example, in the aforementioned embodiments, the example in which the lead frames 3 and 4 are provided on the both sides of the semiconductor device 2 in the thickness direction has been described, but the present disclosure is not limited thereto. For example, like a semiconductor apparatus 1a as a modification of the present disclosure illustrated in FIG. 8, the present disclosure may include the semiconductor device 2, lead frame 3, solder layer 11, sealing resin body 5, wire 7, and terminal 8 without including lead frame 4, metal block 6, etc. It should be noted that in the structure in which the lead frame 3 is provided only on one side of the semiconductor device 2 in the thickness direction as in the semiconductor apparatus la illustrated in FIG. 8, the constraining force of the sealing resin body 5 is smaller and the stress generated in the lead frame 3 is thus smaller, as compared to the structure like the semiconductor apparatus 1 illustrated in FIG. 1. Therefore, in the semiconductor apparatus la, when the concave portions 20 of the lead frame 3 are formed so as to satisfy the aforementioned Formula (2), the adhesion between the lead frame 3 and the sealing resin body 5 can be sufficiently secured.

Further, in the aforementioned second embodiment, the example in which the concave portions 20c are provided in a single row between the innermost peripheral row C1 and the outermost peripheral row C3 is shown, but the concave portions 20c may be provided in a plurality of rows.

All publications, patents and patent applications cited in the present description are herein incorporated by reference as they are.

What is claimed is:

1. A semiconductor apparatus comprising:
a first lead frame;
a semiconductor device bonded to a mounting surface of the first lead frame via a first bonding layer; and
a sealing resin body that covers a surface of the semiconductor device and a surrounding region of the semiconductor device on the mounting surface,
wherein:
in the surrounding region, a plurality of circular concave portions is formed with a predetermined pitch in a plurality of rows so as to surround the semiconductor device, and
when a pitch and a depth of the concave portions arranged in at least an innermost peripheral row of the plurality of rows disposed so as to surround the semiconductor device are represented as P[μm] and H[μm], respectively, and a flexural modulus of elasticity of the sealing resin body is represented as E[GPa], the following Formulae (1) and (2) are satisfied:
E[GPa]≤20[GPa] (1)
5≤86.4−5.45×E[GPa]+0.164×P[μm]≤H[μm] (2).

2. The semiconductor apparatus according to claim 1, wherein the concave portions arranged in each of the rows satisfy the Formula (2).

3. The semiconductor apparatus according to claim 1, wherein the plurality of concave portions include:
first concave portions arranged in the innermost peripheral row;
second concave portions arranged in an outermost peripheral row; and
third concave portions arranged between the innermost peripheral row and the outermost peripheral row, the third concave portions being formed so as to have at least one of a larger pitch and a smaller depth than those of the first concave portions and the second concave portions.

4. The semiconductor apparatus according to claim 1, further comprising:
a metal block bonded, via a second bonding layer, to a surface of the semiconductor device, which is on a side opposite to the first lead frame; and
a second lead frame bonded, via a third bonding layer, to a surface of the metal block, which is on a side opposite to the semiconductor device,
wherein:
the second lead frame has a facing surface disposed so as to face the metal block,
a surrounding region of the metal block on the facing surface is covered with the sealing resin body,
in the facing surface, a plurality of circular concave portions is formed with a predetermined pitch in a plurality of rows so as to surround the metal block, and
the concave portions arranged in at least the innermost peripheral row of the plurality of rows disposed so as to surround the metal block satisfy the Formula (2).
